(19) United States
(12) Patent Application Publication
(10) Pub. No.: US 2025/0338391 A1
(43) Pub. Date: Oct. 30, 2025

(54) Heated Circuit Board Apparatus

(71) Applicant: Dell Products L.P., Round Rock, TX (US)

(72) Inventors: Eric Michael Tunks, Austin, TX (US); Bates James Hunt, Round Rock, TX (US)

(73) Assignee: Dell Products L.P., Round Rock, TX (US)

(21) Appl. No.: 18/650,780

(22) Filed: Apr. 30, 2024

(51) Int. Cl. H05K 1/02; H05K 1/09; H05K 1/18; H05K 7/20

(52) U.S. Cl. CPC H05K 1/0212; H05K 1/09; H05K 1/181; H05K 7/20545; H05K 2201/093; H05K 2201/10166

(57) ABSTRACT

A circuit board having one or more computer-based components comprises a ground plane, such as a copper sheet, and a dielectric layer overlaying the ground plane. An opening is defined in the dielectric layer such that an area of the ground plane is exposed. A heating device is mounted within the opening and thermally coupled to the ground plane such that energizing the heating device transfers heat to the ground plane.

### BACKGROUND

Information handling systems (IHS), particularly, servers and the like, are ubiquitous. In the main, off-the-shelf systems are designed for environments with temperatures ranging from 10° C. to 35° C. If temperatures dip below 0° C., many of the system components fail. Above 35° C., server cooling fans are often unable to maintain the acceptable operating temperature for server components.

However, servers are deployed to far reaches of the planet, calling for systems that can perform in more extreme environments. Hardware systems may be deployed in data centers that are somewhat protected from the weather but may have minimal heating or cooling control. Accordingly, many hardware systems are expected to operate in the temperatures ranging from −40° C. to 65° C. For these environments, solutions include specific designs that may be “ruggedized”, i.e., designed with expensive components with heating and cooling capacity.

Sometimes, additional capability for a server system is desired or required depending on the application. Providers then turn to peripheral cards, also known as “add-in cards” (“AIC”), which are typically off-the-shelf circuit boards supporting computer-based components that are installed in a server, often from third party vendors, to add the desired capability. These AICs are generally not designed to operate in extreme cold environments. Indeed, often components may not even be energized, “booted,” in a cold environment until such components have received a certain amount of heating.

One stop-gap solution is to associate heating elements to the card. For example, a printed circuit board heater may be thermally coupled to card heat sinks. However, this will not work for conventional AICs, which are not designed to be thermally coupled a heater. Printed circuit board (PCB) heaters could work for heating an AIC, if the AIC was designed such that there was a thermal interface point and mechanical attachment features. Further, using additional heaters often leads to inconsistent throughout the card. If this is done without close coordination with the card vendor, it will likely void any vendor warranty.

A low-cost solution is needed to provide peripheral cards capable of being sufficiently heated for servers that operate in extreme cold conditions.

### SUMMARY

For purposes of summary, certain aspects, advantages, and novel features are described herein. It will be understood that all such advantages may not be achieved in accordance with any one particular embodiment. Thus, the apparatuses or methods claimed may be embodied or carried out in a manner that achieves or optimizes one advantage or group of advantages as taught herein without necessarily achieving other advantages as may be taught or suggested herein.

A circuit board having one or more computer-based components comprises a copper sheet and a dielectric layer overlaying the copper sheet. An opening is defined in the dielectric layer such that an area of the copper sheet is exposed. A heating device is mounted within the opening and thermally coupled to the copper sheet such that energizing the heating device transfers heat to the copper sheet.

In one embodiment, the heating device is responsive to a heater manager that is configured to provide control signals in response to temperature feedback received from temperature sensors associated with the computer-based components.

In one embodiment, the circuit board is configured with the heater manager.

In one embodiment, the circuit board is associated with a server and the server is configured with the heater manager.

In yet another embodiment, the heating device may be a MOSFET heating device.

Another aspect of the heated circuit board incorporates a second dielectric layer on the opposite side of the copper sheet from the first dielectric layer where the second dielectric layer includes an opening such that a second area of the copper sheet is exposed. A second heating device is mounted in the second opening and is also thermally coupled to the copper sheet.

### BRIEF DESCRIPTION OF THE DRAWINGS

The present system is illustrated by way of example and is not limited by the accompanying figures. Elements in the figures are illustrated for simplicity and clarity and have not necessarily been drawn to scale. In the drawings, like reference numbers indicate identical or functionally similar elements. Additionally, the left-most digit(s) of a reference number identifies the drawing in which the reference number first appears.

FIG. 1 an exemplary circuit board adapted for use in one embodiment of the system;

FIG. 2A is a cross-section view of a circuit board according to the embodiment illustrated in FIG. 1;

FIG. 2B is a cross-section view of a second circuit board according to a second embodiment;

FIG. 3A is a functional schematic of a server system with a heated circuit board installed;

FIG. 3B is a functional schematic of a heated circuit board; and

FIG. 3C shows an exemplary network architecture where component temperature sensors are associated with components on a circuit board; and

FIG. 4 is a graphical representation of the heat transfer generated by a simulation of a heated circuit board.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

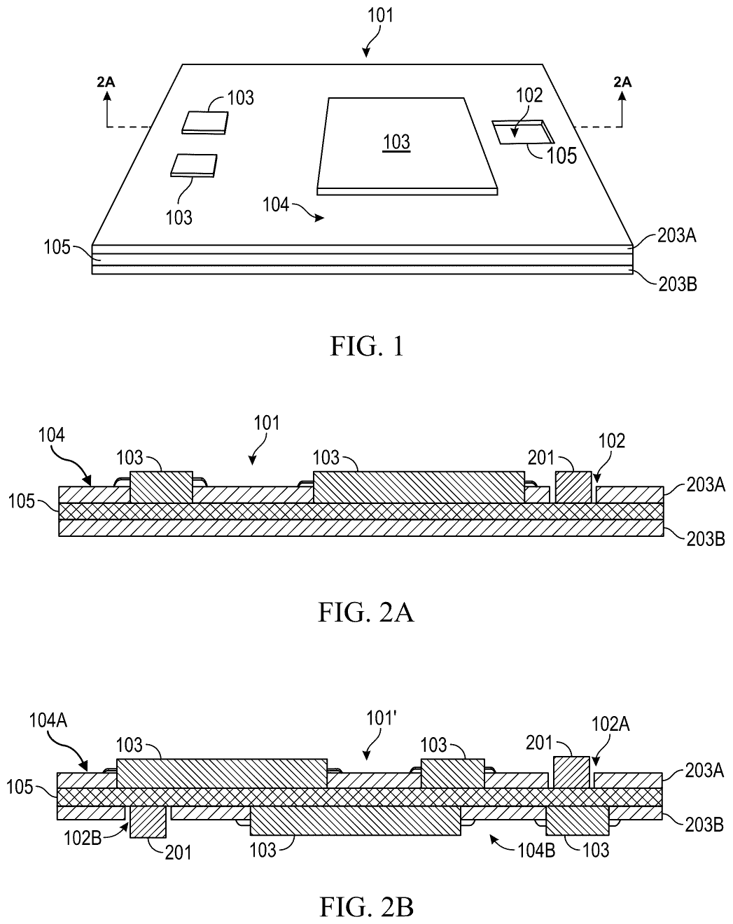

FIG. 1 illustrates a circuit board 101 supporting computer-based components 103 on the surface 104 thereof. Components 103 may be, for example, CPUs, GPUs, and/or memory devices that are sensitive to environmental temperatures during bootup and operation. As used herein, the term, “circuit board,” should be understood to comprise one or more dielectric layer(s) 203a,b. A substrate comprising fiberglass-reinforced epoxy laminate (e.g., FR4) may be used as the dielectric in some embodiments. A circuit board typically also includes one or more layers of copper sheeting 105 sandwiched between dielectric layer(s) 203a,b. Copper sheeting 105 may function as a ground plane for components 103. An opening 102 is defined in the surface of dielectric layer 203a to expose copper sheet 105. Opening 102 may be created during manufacture of circuit board 101, such as using a mold or form. Alternatively, opening 102 may be created by removing the dielectric material 203a from the area 102 when components 103 are being mounted on board 101. While copper sheet is often used for a ground plane layer 105, it will be understood that in other embodiments other electrically and thermally conductive materials may be used as the ground plane layer 105.

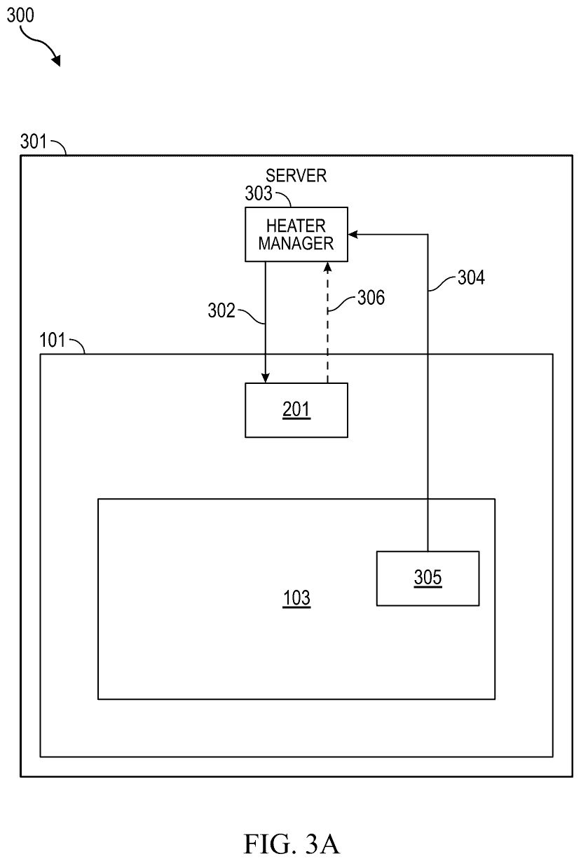

FIG. 2A presents a cross-section view of the circuit board of FIG. 1, showing one or more dielectric layers 203a,b, with opening 102 defined in the top surface 104 of the upper layer 203a. Copper sheet 105 is interposed between layers 203a,b. A section of the copper sheet 105 is exposed by opening 102. Components 103 are mounted on circuit board 101 such that they are in physical contact with copper sheet 105 and are, therefore, thermally coupled to copper sheet 105. Copper sheet 105 may be a ground plane for components 103 in one embodiment. A heating device 201 is received in opening 102 and is thermally coupled to copper sheet 105. Heating device 201 may be attached to copper sheet 105 using solder or a thermally conductive adhesive. In other embodiments, a clip or mechanical attachment on dielectric layer 203a may hold heating device 201 in place and thermally connected to ground plane 105.

Heating device 201 comprises a heating element for conducting heat to copper sheet 105. In a one embodiment, heating device 201 is connected to a power supply, typically an AC or DC source, that provides the electrical energy needed for heating. As described hereafter, power may be supplied from the server or from circuit board components 103. Heating device 201 may include a control circuit, which may be implemented using microcontrollers or dedicated heater control modules that generate the appropriate control signals to regulate output power of the heating device 201.

Heating device 201 includes a heating element that generates heat when current flows through it. the heating element is typically made of a resistive material with high electrical resistance, such as nichrome wire or a ceramic heating element. Heating device 201 may also include temperature sensors, such as thermocouples or resistance temperature detectors (RTDs), to provide feedback on the heater's temperature. This feedback can be used to implement closed-loop temperature control algorithms for precise temperature regulation. In one embodiment, heating device 201 may be a Metal-Oxide-Semiconductor Field-Effect Transistor (MOSFET) device. Switches or amplifiers in the control circuitry can modulate the current flowing through the MOSFET heating element based on the control signals received. Advantageously, such MOSFET heaters offer advantages such as fast response times, high efficiency, and precise temperature control. In other embodiments, flexible polyimide/silicone heaters, cartridge heaters, or Positive Temperature Coefficient (PTC) heaters would also work as the heating device 201.

It will be appreciated that copper is a highly thermally conductive metal. It is commonly used in applications where heat needs to be efficiently transferred, spread, or dissipated, such as in heat sinks. Copper's high thermal conductivity allows it to rapidly transfer heat from a heat source. Consequently, energizing heating device 201 transfers heat to copper sheet 105. That heat is then spread throughout copper sheet 105 and throughout the circuit board 101 adding heat to components 103, which are in thermal contact with copper sheet 105.

FIG. 2B shows a second embodiment of a circuit board 101′ comprising first and second dielectric layers 203a,b. A ground plane, such as a copper sheet, 105 is interposed between dielectric layers 203a,b. Components 103 are mounted to the outer surfaces 104a,b of dielectric layers 203a,b. A first opening 102a is defined in surface 104a of the upper dielectric layer 203a exposing an area of copper sheet 105. A first heating device 201 is received within opening 102a and is thermally coupled to copper sheet 105 as described above. Similarly, a second opening 102b is defined in the outer surface 104b of second dielectric layer 203b. Second opening 102b exposes an area of copper sheet 105 at a different region of circuit board 101′ compared to opening 102a. A second heating device 201b is received in opening 102b and is thermally coupled to copper sheet 105 in that region.

In the illustrated example, components 103 are mounted to both sides of board 101′ such that they are in contact with copper sheet 105 and are, therefore, thermally coupled to copper sheet ground plane 105. The advantages of this configuration will be apparent to those skilled in the relevant art. Heat may be conducted to copper sheet 105 from either side thereof to components 103 on both sides of board 101′ resulting in greater and more consistent heat dispersion. Further, placing a heating device 201 and either end of board 101′ would result in more thorough and consistent heating of components 103 throughout the length of board 101′. It should be further noted that a board 101′ could be contrived with two or more heating devices 201 on the same side but on opposite ends of the board 101 depending on the size of the board.

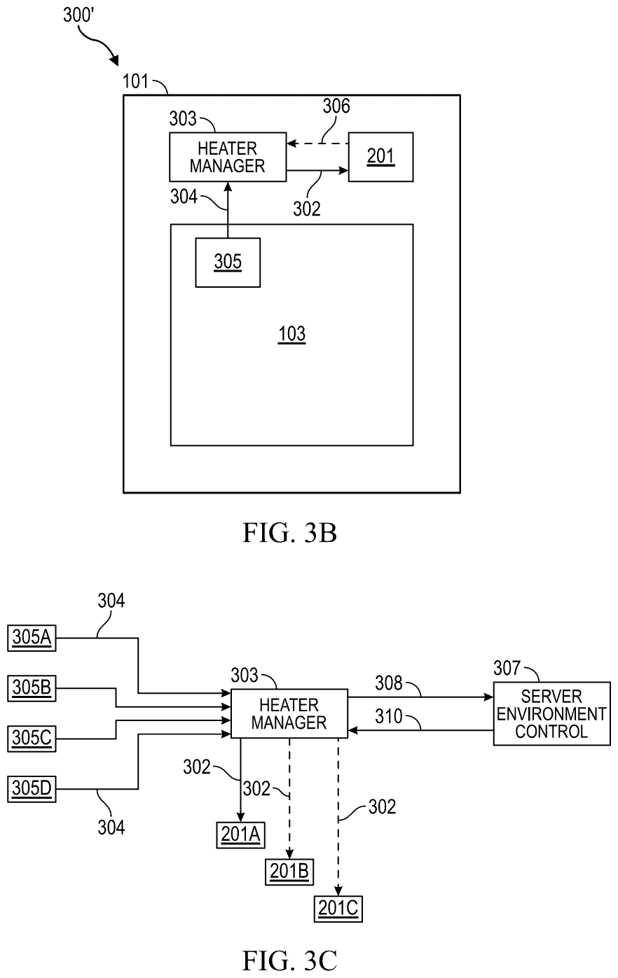

Referring to FIG. 3A, a server system 301 comprises a heated circuit board 101 with a computer-based component 103 mounted thereto and a heating device 201 mounted within opening 102 (as illustrated in FIGS. 1-2A). In other embodiments, circuit board 101 may have any number of thermally conductive ground plane layers that are attached to any number of heating elements 201 (such as the multiple heater example of FIG. 2B). Server 301 comprises a heater manager 303 for controlling heating device(s) 201. Heater manager 303 provides power and/or control signals 302 to heating device 201. A temperature sensor 305 is associated with component 103 and provides signals 304 that represent component temperature to heater manager 303, thus forming a feedback loop.

Heater manager 303 may be a computer-based device or process that is configured to receive as component temperature signals 304 from component temperature sensor 305 as an input and, in response, to regulate power to heating device 201 through control signal 302. Heater manager 303 may also be configured to relay component temperature data to server 301. Temperature data signal 304 from temperature sensor 305, relayed by heater manager 303, may indicate to server 301 that component 103 is not warm enough to energize, or “boot up.” In that case, heater manager 303 may continue energizing heating device 201 before initiating the boot sequence. Likewise, temperature data signal 304 from temperature sensor 305, relayed by heater manager 303, may indicate component 103 temperature has exceeded the threshold for booting it up in which case server may initiate a component 103 boot sequence.

In some embodiments, heating device 201 may be configured with a temperature sensor (not shown). In such case, heater manager 303 may be configured to receive signals 306 representative of the temperature of heating device 201. Heater manager 303 may use this temperature signal 306 to regulate power to heating device 201 accordingly.

In another embodiment, depicted in FIG. 3B, heater manager 303 is associated with circuit board 101 (or any other circuit board configuration, such as board 101′). Heater manager 303 provides power/control signals 302 to heating device 201 in response to signals 304 representative of component temperature received from temperature sensor 305 associated with component 103. In this embodiment, circuit board 101 may be configured to provide power to heating device 201.

FIG. 3C shows an exemplary network architecture where component temperature sensors 305a-d are associated with components on a circuit board. A heater manager 303 is associated with the circuit board or implemented elsewhere in a server system. Heater manager 303 may be configured to receive temperature data signals 304 from temperature sensors 305a-d. Heater manager 303 then relays temperature data extracted from signals 304 to server environment control 307. Server environment control 307 may issue control signals 310 to heater manager 303, which in turn issues control signals 302 to one or more heating devices 201a-c. Server environment control 307 may also issue control signals to regulate ambient temperature, namely, signals to control flappers or shutters that allow ambient air into the server environment.

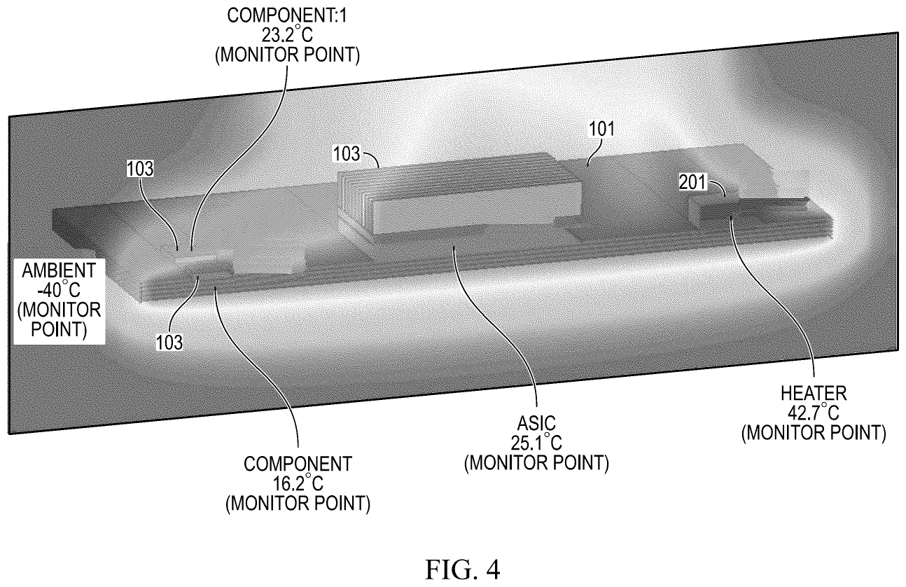

To demonstrate the effectiveness of this solution, the heated circuit board embodiment shown in FIG. 1 was input into a thermal simulation and a graphical heat map representing heat transfer through the simulated board is illustrated in FIG. 4. It can be seen that with an ambient temperature of −40° C., configuring a circuit board 101 with a heating device 201 in thermal contact with the copper sheet 105 (not shown in FIG. 4), and heating the copper sheet 105, results in significantly consistent and efficient heat transfer. Indeed, with the heating device 201 temperature up to 42.7° C., temperature at components 103 range from 16.2° C. to 25.1° C.

The heated circuit boards described herein may be peripheral cards or AICs supporting computer-based components that are installed in a server or IHS. An IHS may be a single-processor system, or a multi-processor system including two or more processors. Host processors on the IHS may include any processor capable of executing program instructions, such as an INTEL/AMD x86 processor, or any general-purpose or embedded processor implementing any of a variety of Instruction Set Architectures (ISAs), such as a Complex Instruction Set Computer (CISC) ISA, a Reduced Instruction Set Computer (RISC) ISA (e.g., one or more ARM core(s), or the like). The IHS may include a chipset coupled to the host processors. The chipset may provide host processors with access to several resources on the IHS. In some cases, the chipset may utilize a QuickPath Interconnect (QPI) bus to communicate with the host processors. The chipset may also be coupled to communication interfaces to enable communications between the IHS and various wired and/or wireless networks, such as ETHERNET, WIFI, BLUETOOTH (BT), cellular or mobile networks (e.g., Code-Division Multiple Access or “CDMA,” Time-Division Multiple Access or “TDMA,” Long-Term Evolution or “LTE,” etc.), satellite networks, or the like.

The IHS may assume different form factors including, but not limited to: servers, workstations, desktops, laptops, appliances, video game consoles, tablets, smartphones, etc. For purposes of this disclosure, an IHS may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an IHS may be a personal computer (e.g., desktop or laptop), tablet computer, mobile device (e.g., Personal Digital Assistant (PDA) or smart phone), server (e.g., blade server or rack server), a network storage device, or any other suitable device and may vary in size, shape, performance, functionality, and price.

An IHS may include Random Access Memory (RAM), one or more processing resources such as a Central Processing Unit (CPU) or hardware or software control logic, Read-Only Memory (ROM), and/or other types of nonvolatile memory. Additional components of an IHS may include one or more disk drives, one or more network ports for communicating with external devices as well as various I/O devices, such as a keyboard, a mouse, touchscreen, and/or a video display. An IHS may also include one or more buses operable to transmit communications between the various hardware components.

The IHS may operate in extreme weather conditions, such as cold weather climates that require supplemental heating to ensure IHS components are within a required operating temperature range.

A circuit board having one or more computer-based components, the circuit board comprising a ground plane; a dielectric layer overlaying the ground plane, the dielectric layer having an opening defined therein such that an area of the ground plane is exposed; and a heating device mounted within the opening and thermally coupled to the ground plane such that energizing the heating device transfers heat to the ground plane. The ground plane is metallic or otherwise both electrically and thermally conductive. The heating device can be a MOSFET heating device having a heating element thermally coupled to the ground plane. The ground plane can be a copper sheet or layer in multi-layer circuit board.

The circuit board may further comprise a heating manager device to which the heating device is responsive. The one or more computer-based components may comprise a temperature sensor responsive to the heating manager device. The heating device can be a MOSFET heating device having a heating element thermally coupled to the ground plane.

The circuit board can be associated with a computer-based server or an IHS. The heating device can be responsive to a heating manager device associated with the server. The one or more computer-based components comprises a temperature sensor responsive to the heating manager device. The heating device can be a MOSFET heating device having a heating element thermally coupled to the ground plane. The ground plane is a metallic layer, such as a copper sheet.

The circuit board may further comprise a second dielectric layer overlaying an opposing side of the copper sheet and having a second opening defined therein such that a second area of the ground plane is exposed; and a second heating device mounted within the second opening and thermally coupled to the ground plane such that energizing the heating device transfers heat to the ground plane. The circuit board may further comprise a heating manager device to which the heating device is responsive. The one or more computer-based components comprises a temperature sensor responsive to the heating manager device. The circuit board is associated with a computer-based server or an IHS. The heating device is responsive to a heating manager device associated with the server and wherein the one or more computer-based components comprises a temperature sensor responsive to the heating manager device.

In another embodiment, a peripheral card for an information handling system comprises a multi-level circuit board having a top layer comprising a dielectric material and a ground plane layer below the top layer; at least one electronic component mounted on the peripheral card; and a heating element mounted within a hole in the top layer and attached directly to the ground plane. The heating element is configured to generate when in an operating state. The heating element is further configured to operate in response to commands from a heater manager. The heating element is configured to heat the ground plane and the at least one electronic component is configured to absorb heat thermally conducted from the heating element via the ground plane. The heating element is a MOSFET transistor. The heater manager is a component of the information handling system in which the peripheral card is mounted, such as an application or module running on the information handling system. The at least one component is electrically coupled to the ground plane.

Although the hardware is described herein with reference to specific embodiments, various modifications and changes can be made without departing from the scope of the present invention, as set forth in the claims below. Accordingly, the specification and figures are to be regarded in an illustrative rather than a restrictive sense, and all such modifications are intended to be included within the scope of any invention appertaining thereto. Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

What is claimed is:

1. A circuit board having one or more computer-based components, the circuit board comprising:
a ground plane;
a dielectric layer overlaying the ground plane, the dielectric layer having an opening defined therein such that an area of the ground plane is exposed; and
a heating device mounted within the opening and thermally coupled to the ground plane such that energizing the heating device transfers heat to the ground plane.

2. The circuit board of claim 1, wherein the heating device is a MOSFET heating device having a heating element thermally coupled to the ground plane.

3. The circuit board of claim 2, wherein the ground plane is a copper sheet.

4. The circuit board of claim 1, further comprising a heating manager device to which the heating device is responsive.

5. The circuit board of claim 4, wherein the one or more computer-based components comprises a temperature sensor responsive to the heating manager device.

6. The circuit board of claim 5, wherein the heating device is a MOSFET heating device having a heating element thermally coupled to the ground plane.

7. The circuit board of claim 6, wherein the ground plane is a copper sheet.

8. The circuit board of claim 1, wherein the circuit board is associated with a computer-based server.

9. The circuit board of claim 8, wherein the heating device is responsive to a heating manager device associated with the server.

10. The circuit board of claim 9, wherein the one or more computer-based components comprises a temperature sensor responsive to the heating manager device.

11. The circuit board of claim 10, wherein the heating device is a MOSFET heating device having a heating element thermally coupled to the ground plane.

12. The circuit board of claim 11, wherein the ground plane is a copper sheet.

13. The circuit board of claim 1, further comprising:
a second dielectric layer overlaying an opposing side of the copper sheet and having a second opening defined therein such that a second area of the ground plane is exposed; and
a second heating device mounted within the second opening and thermally coupled to the ground plane such that energizing the heating device transfers heat to the ground plane.

14. The circuit board of claim 13, further comprising a heating manager device to which the heating device is responsive.

15. The circuit board of claim 14, wherein the one or more computer-based components comprises a temperature sensor responsive to the heating manager device.

16. The circuit board of claim 13, wherein the circuit board is associated with a computer-based server.

17. The circuit board of claim 16, wherein the heating device is responsive to a heating manager device associated with the server and wherein the one or more computer-based components comprises a temperature sensor responsive to the heating manager device.

18. A peripheral card for an information handling system comprises:
a multi-level circuit board having a top layer comprising a dielectric material and a ground plane layer below the top layer;
at least one electronic component mounted on the peripheral card; and
a heating element mounted within a hole in the top layer and attached directly to the ground plane, the heating element configured to generate when in an operating state, the heating element further configured to operate in response to commands from a heater manager, wherein the heating element is configured to heat the ground plane and the at least one electronic component is configured to absorb heat thermally conducted from the heating element via the ground plane.

19. The peripheral card of claim 18, wherein the heating element is a MOSFET transistor, and the heater manager is a component of the information handling system in which the peripheral card is mounted.

20. The peripheral card of claim 18, wherein the at least one component is electrically coupled to the ground plane.
